(19) United States
(12) Patent Application Publication
(10) Pub. No.: US 2026/0018523 A1
(43) Pub. Date: Jan. 15, 2026

(54) SEMICONDUCTOR PACKAGE

(71) Applicant: Samsung Electronics Co., Ltd., Suwon-si (KR)

(72) Inventors: Ju Hyeon OH, Suwon-si (KR); Seok Geun AHN, Suwon-si (KR)

(73) Assignee: Samsung Electronics Co., Ltd., Suwon-si (KR)

(21) Appl. No.: 19/261,676

(22) Filed: Jul. 7, 2025

(30) Foreign Application Priority Data
Jul. 9, 2024 (KR) 10-2024-0090043

(51) Int. Cl. H01L 23/538; G02B 6/12; H01L 23/00; H01L 23/31; H01L 23/48; H01L 25/16

(52) U.S. Cl. CPC H01L 23/5383; G02B 6/12; H01L 23/3135; H01L 23/481; H01L 23/562; H01L 25/167

(57) ABSTRACT

A semiconductor package may include a first semiconductor chip including a first area, a second area, an optical conversion device that is in the first area, and vertical wires that are in the second area, the optical conversion device being configured to receive an optical signal and convert it into an electrical signal, a first dummy chip on the first semiconductor chip and at least partially overlapping with the first area, a second semiconductor chip at least partially overlapping with the second area, a wiring layer between the first and second semiconductor chips and including first wiring patterns that connect the vertical wires and the second semiconductor chip, and second wiring patterns that at least partially overlap with the first dummy chip, and a second dummy chip on the first dummy chip and on the second semiconductor chip.

### CROSS-REFERENCE TO RELATED APPLICATION

This application claims priority from Korean Patent Application No. 10-2024-0090043 filed on Jul. 9, 2024 in the Korean Intellectual Property Office, and all the benefits accruing therefrom under 35 U.S.C. 119, the contents of which in its entirety are herein incorporated by reference.

### BACKGROUND

### 1. Field

Inventive concepts relate to a semiconductor package.

### 2. Description of the Related Art

A semiconductor package may be understood as an implementation of integrated circuit (IC) chips in a form suitable for use in an electronic product. Typically, a semiconductor package is fabricated by mounting semiconductor chips on a printed circuit board (PCB) and electrically connecting them using bonding wires or bumps. With the development of the electronics industry, various studies are being conducted to improve the reliability of semiconductor packages.

To meet the demands for miniaturization and increased speed of electronic devices, the acceleration of signal transmission may be advantageous. However, since electrical signals are transmitted through wiring such as copper wires, which may limitations with respect to relatively higher speeds, a signal transmission method using optical signals may be advantageous. Accordingly, there is a desire for an optical IC package for transmitting optical signals.

### SUMMARY

Aspects of inventive concepts relate to, for example, a semiconductor package with improved reliability and/or methods of fabrication thereof.

However, aspects of inventive concepts are not restricted to those set forth herein. The above and other aspects of inventive concepts will become more apparent to one of ordinary skill in the art to which inventive concepts pertain by referencing the detailed description of some example embodiments given below.

According to some example embodiments, a semiconductor package may include a first semiconductor chip including a first area, a second area, an optical conversion device that is in the first area, and vertical wires that are in the second area the optical conversion device being configured to receive an optical signal and converts it into an electrical signal, a first dummy chip on the first semiconductor chip and at least partially overlapping with the first area, a second semiconductor chip on the first semiconductor chip and at least partially overlapping with the second area, a wiring layer between the first and second semiconductor chips and including first wiring patterns that connect the vertical wires and the second semiconductor chip, and second wiring patterns that at least partially overlap with the first dummy chip, and a second dummy chip on the first dummy chip and the second semiconductor chip.

According to some example embodiments of inventive concepts, a semiconductor package may include a first semiconductor chip including a first area, a second area, an optical conversion device that is in the first area, and vertical wires that are in the second area, the optical conversion device being configured to receive an optical signal and converts it into an electrical signal, a first dummy chip on the first semiconductor chip and at least partially overlapping with the first area, a second semiconductor chip on the first semiconductor chip and at least partially overlapping with the second area, a wiring layer between the first and second semiconductor chips and including first wiring patterns that connect the vertical wires and the second semiconductor chip, and a second dummy chip disposed on the first dummy chip and on the second semiconductor chip, wherein the first dummy chip is in direct contact with the first semiconductor chip.

According to some example embodiments of inventive concepts, a semiconductor package may include an interposer and a photonic semiconductor package on the interposer, wherein the photonic semiconductor package includes a first semiconductor chip including a first area, a second area, an optical conversion device that is in the first area, and vertical wires that are in the second area, the optical conversion device being configured to receive an optical signal and convert it into an electrical signal, a first dummy chip on the first semiconductor chip and at least partially overlapping with the first area a second semiconductor chip at least partially overlapping with the second area, on the first semiconductor chip; an encapsulation layer between the first dummy chip and the second semiconductor chip, a wiring layer between the first and second semiconductor chips and including first wiring patterns that connect the vertical wires and the second semiconductor chip, and second wiring patterns between the first dummy chip and the first semiconductor chip, and a second dummy chip on the first dummy chip and on the second semiconductor chip.

It should be noted that the effects of inventive concepts are not limited to those described above, and other effects of inventive concepts will be apparent from the following description.

### BRIEF DESCRIPTION OF THE DRAWINGS

The above and other aspects and features of inventive concepts will become more apparent by describing in detail example embodiments thereof with reference to the attached drawings, in which:

FIG. 1 is a diagram illustrating a semiconductor package according to some example embodiments.

FIG. 2 is a diagram illustrating the operation of the semiconductor package according to some example embodiments.

FIGS. 3 through 8 are diagrams illustrating a method of manufacturing the semiconductor package of FIG. 1.

FIG. 9 is a diagram illustrating a semiconductor package that includes the semiconductor package of FIG. 1.

FIGS. 10 and 11 are diagrams illustrating semiconductor packages according to some example embodiments.

FIG. 12 is an enlarged view explaining region X of FIG. 11.

FIG. 13 is a diagram illustrating a semiconductor package according to some example embodiments.

FIGS. 14 through 16 are diagrams illustrating semiconductor packages according to some example embodiments.

### DETAILED DESCRIPTION

Example embodiments of inventive concepts will hereinafter be described with reference to the accompanying drawings. The same reference numerals are used for the same components in the drawings, and thus, redundant explanations thereof will be omitted.

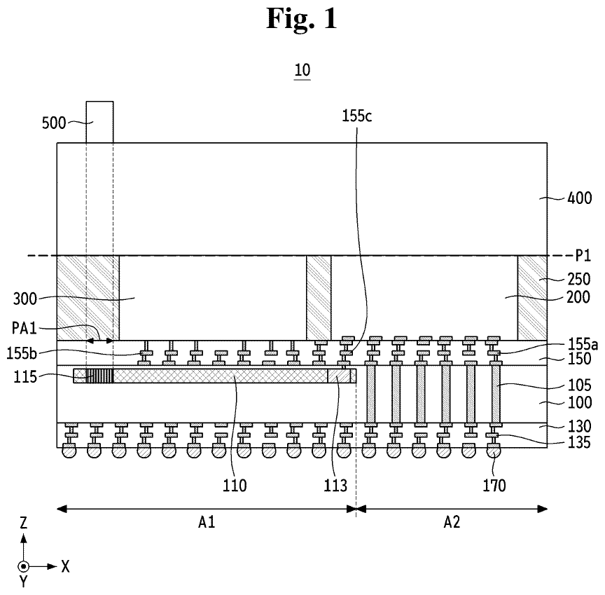

FIG. 1 is a diagram illustrating a semiconductor package according to some example embodiments.

Referring to FIG. 1, a semiconductor package 10 may include a first semiconductor chip 100, an upper wiring layer 150, a lower wiring layer 130, a second semiconductor chip 200, a first dummy chip 300, a second dummy chip 400, and an optical fiber 500.

The first semiconductor chip 100 may include a first area A1 and a second area A2 on a substrate. In the first area A1, an optical conversion device may be installed. In the second area A2, vertical wires 105 may be installed. For example, the first semiconductor chip 100 may be or include a photonic integrated circuit (PIC).

In some example embodiments, the optical conversion device may include a coupler 115, a waveguide 110, and an optical converter 113.

The coupler 115, the waveguide 110, and the optical converter 113 may be optically coupled to each other to transmit and receive signals.

The coupler 115 may be or include, for example, a vertical optical coupler. The coupler 115 may, for example, couple light in a vertical direction. The coupler 115 may couple light traveling in a horizontal direction on a PIC substrate 102 into the vertical direction. The coupler 115 may be installed in a position that overlaps (for example, at least partially overlaps) with the optical fiber 500 in a first direction (or a Z-axis direction).

The waveguide 110 may be a path through which light (for example, optical signals) travels. The waveguide 110 may transmit optical signals received from the coupler 115 in the horizontal direction to the optical converter 113. Additionally, or alternatively, the waveguide 110 may transmit optical signals generated by the optical converter 113 in the horizontal direction to the coupler 115.

The optical converter 113 may be optically coupled to the waveguide 104 to interact with the optical signals within the waveguide 110. The optical converter 113 may include, for example, a photodiode (PD) and/or a modulator, but example embodiments are not limited thereto.

For example, the PD may detect optical signals incident in the vertical direction from the optical fiber 500 to the semiconductor package 10 and convert them into electrical signals. Additionally, or alternatively, the modulator may detect the electrical signals and convert them into optical signals.

The vertical wiring 105 may be connected to first upper wiring patterns 155a of the upper wiring layer 150 and electrically connected to lower wiring patterns 135 of the lower wiring layer 130. Accordingly, the configuration within the semiconductor package 10 can be electrically connected to the outside.

The upper wiring layer 150 may be formed on the first semiconductor chip 100. The upper wiring layer 150 may include, for example, the first upper wiring patterns 155a, second upper wiring patterns 155b, and third upper wiring patterns 155c.

The first upper wiring patterns 155a may be installed to overlap (for example, at least partially overlap) with the second semiconductor chip 200 in the first direction (or the Z-axis direction), and may be connected to the vertical wires 105 and the second semiconductor chip 200. The second upper wiring patterns 155b may be installed to overlap (for example, at least partially overlap) with the first dummy chip 300 in the first direction (or the Z-axis direction). The second upper wiring patterns 155b may not be electrically connected to the first dummy chip 300. For example, the second upper wiring patterns 155b may be or include dummy wiring patterns, but example embodiments are not limited thereto. Additionally, the second upper wiring patterns 155b may not be electrically connected to the first upper wiring patterns 155a. Accordingly, the upper wiring layer 150 may be provided with a uniform metal density, which can reduce or prevent dishing and erosion phenomena that may occur during, for example, a chemical mechanical polishing (CMP) process. Accordingly, a semiconductor package with improved reliability and/or quality may be provided. The third upper wiring patterns 155c may be connected to the optical converter 113 and the second semiconductor chip 200. Accordingly, the electrical signals generated by the optical converter 113 can be transmitted to the second semiconductor chip 200, and electrical signals can be transmitted from the second semiconductor chip 200 to the optical converter 113.

The second semiconductor chip 200 may be formed on the upper wiring layer 150. Additionally, the second semiconductor chip 200 may be disposed to overlap (for example, at least partially overlap) with the second area A2 in the first direction (or the Z-axis direction). For example, the second semiconductor chip 200 may be or include an electronic integrated circuit (EIC), but the example embodiments are not limited thereto. The second semiconductor chip 200 may be electrically connected to the lower wiring layer 130 through the first upper wiring patterns 155a. Furthermore, the second semiconductor chip 200 may be electrically connected to the optical converter 113 through the third upper wiring patterns 155c.

The first dummy chip 300 may be formed on the upper wiring layer 150. Additionally, the first dummy chip 300 may be disposed to overlap with the first area A1 in the first direction (or the Z-axis direction). The first dummy chip 300 may include a material such as, for example, silicon, silicon oxide, or a metal, but example embodiments are not limited thereto. As the second semiconductor chip 200 and the first dummy chip 300 are disposed together on the upper wiring layer 150, heat can be evenly or substantially evenly distributed within the semiconductor package 10, and the structural balance of the semiconductor package 10 can be maintained, or substantially so. As a result, warpage can be reduced, and a semiconductor package 10 with improved performance and reliability can be provided.

The upper surfaces of the first dummy chip 300 and the second semiconductor chip 200 may be positioned on the same plane. For example, the upper surfaces of the first dummy chip 300 and the second semiconductor chip 200 may both be located on a first plane P1.

The semiconductor package 10 may include an encapsulation layer 250 that seals the first dummy chip 300 and/or the second semiconductor chip 200. The encapsulation layer 250 may be, for example, formed of a material that is optically transparent, but example embodiments are not limited thereto. For example, the encapsulation layer 250 may include borosilicate glass, silica glass, methyl methacrylate (MMA), and/or polycarbonate (PC), etc., but example embodiments are not limited thereto. Accordingly, optical signals input through the optical fiber 500 can be transmitted to the coupler 115.

The second dummy chip 400 may be formed on the first dummy chip 300 and the second semiconductor chip 200. The second dummy chip 400 may include a material such as, for example, silicon, silicon oxide, or a metal, but example embodiments are not limited thereto. The second dummy chip 400 may be formed to match the height of the semiconductor package 10 with that of an adjacent semiconductor package 10. This will be described later in further detail.

The optical fiber 500 may be formed on the second dummy chip 400. Additionally, in some example embodiments, the optical fiber 500 may be formed to overlap with the coupler 115 in the first direction (or the Z-axis direction). Accordingly, optical signals input through the optical fiber 500 can be transmitted to the coupler 115. However, inventive concepts are not limited thereto. For example, the optical fiber 500 may also be formed in an inclined shape.

A plurality of external connection terminals 170 may be attached to the lower portion of the lower wiring layer 130. The external connection terminals 170 can connect the semiconductor package 10 to the outside. In some example embodiments, the external connection terminals 170 may be or include solder bumps and/or solder balls. The external connection terminals 170 may be formed of (for example, include), for example, copper (Cu), aluminum (Al), silver (Ag), tin (Sn), gold (Au), any alloys thereof, and/or solder, but example embodiments are not limited thereto.

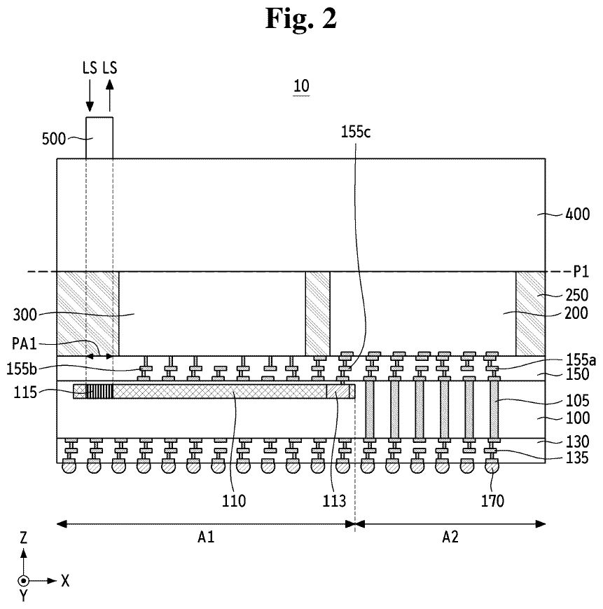

FIG. 2 is a diagram illustrating the operation of the semiconductor package according to some example embodiments.

Referring to FIG. 2, in some example embodiments, an optical signal LS input through the optical fiber 500 may pass through the second dummy chip 400, the encapsulation layer 250, and the upper wiring layer 150, and may be transmitted to the coupler 115. The input optical signal LS transmitted to the coupler 115 may be transmitted along the waveguide 110 in a second direction (an X-axis direction), and may then be provided to the optical converter 113. The optical converter 113 may convert the input optical signal LS into an electrical signal. The optical converter 113 may be electrically connected to the second semiconductor chip 200 by the third upper wiring patterns 155c, and the electrical signal generated by the optical converter 113 may be transmitted to the second semiconductor chip 200 along the third upper wiring patterns 155c. The second semiconductor chip 200 may be electrically connected to the outside of the semiconductor package 10 through the first upper wiring patterns 155a and the vertical wires 105, and the electrical signal transmitted to the second semiconductor chip 200 may be transmitted to the outside of the semiconductor package 10.

Additionally, in some example embodiments, the second semiconductor chip 200 may be electrically connected to the outside of the semiconductor package 10 through the first upper wiring patterns 155a and the vertical wires 105, and the input optical signal LS from the outside may be transmitted to the second semiconductor chip 200 through the first upper wiring patterns 155a and the vertical wires 105. Furthermore, the second semiconductor chip 200 may be electrically connected to the optical converter 113 by the third upper wiring patterns 155c, and the electrical signal transmitted to the second semiconductor chip 200 may be transmitted to the optical converter 113 along the third upper wiring patterns 155c. The optical converter 113 may convert the electrical signal into an optical signal LS. The optical signal LS generated by the optical converter 113 may be transmitted along the waveguide 110 in the second direction (or the X-axis direction) to the coupler 115. The optical signal LS transmitted to the coupler 115 may pass through the upper wiring layer 150, the encapsulation layer 250, and the second dummy chip 400, and may be transmitted to the optical fiber 500. The optical signal LS transmitted to the optical fiber 500 may be output through the optical fiber 500.

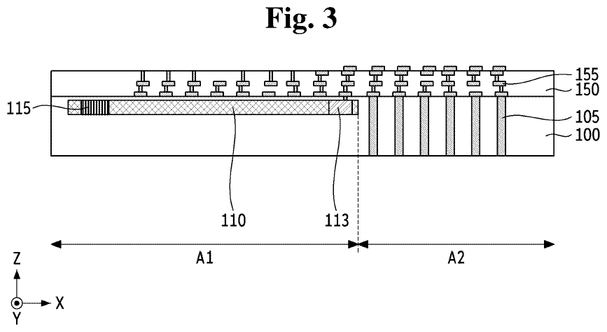

FIGS. 3 through 8 are diagrams illustrating a method of manufacturing the semiconductor package of FIG. 1.

Referring to FIG. 3, the upper wiring layer 150 may be formed on the first semiconductor chip 100.

The first semiconductor chip 100 may include the first and second areas A1 and A2 on the substrate. The optical conversion device may be installed in the first area A1. In some example embodiments, the optical conversion device may include the coupler 115, the waveguide 110, and the optical converter 113. The vertical wires 105 may be installed in the second area A2. For example, the first semiconductor chip 100 may be or include a PIC.

The upper wiring layer 150 may include a plurality of upper wiring patterns. The vertical wires 105 may be electrically connected to some of the upper wiring patterns.

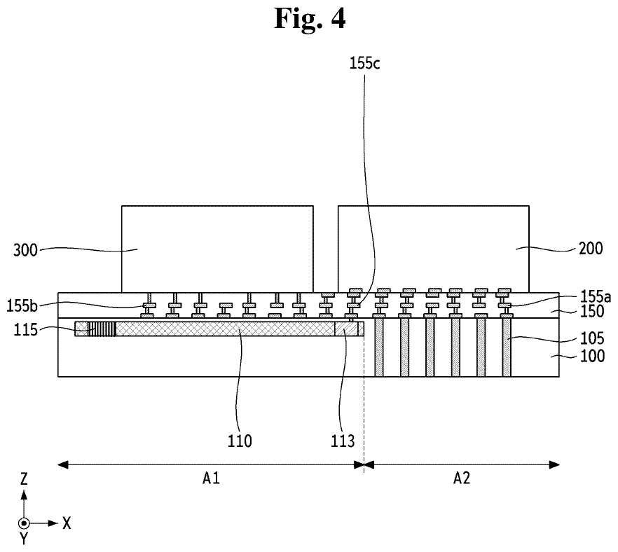

Referring to FIG. 4, the upper wiring layer 150 may include the first upper wiring patterns 155a, the second upper wiring patterns 155b, and the third upper wiring patterns 155c.

The first upper wiring patterns 155a may be installed to overlap with the second semiconductor chip 200 in the first direction (or the Z-axis direction). The second upper wiring patterns 155b may be installed to overlap with the first dummy chip 300 in the first direction (or the Z-axis direction). The second upper wiring patterns 155b may not be electrically connected to the first dummy chip 300. For example, the second upper wiring patterns 155b may be or include dummy wiring patterns. Additionally, the second upper wiring patterns 155b may not be electrically connected to the first upper wiring patterns 155a. Accordingly, the upper wiring layer 150 may be provided with a uniform metal density, which can reduce or prevent dishing and erosion phenomena that may occur during a CMP process. For example, a semiconductor package with improved reliability and quality can be provided. The third upper wiring patterns 155c may be connected to the optical converter 113 and the second semiconductor chip 200. Accordingly, electrical signals generated by the optical converter 113 can be transmitted to the second semiconductor chip 200, and electrical signals can be transmitted from the second semiconductor chip 200 to the optical converter 113.

The second semiconductor chip 200 may be formed on the upper wiring layer 150. Additionally, the second semiconductor chip 200 may be disposed to overlap with the second area A2 in the first direction (or the Z-axis direction). The second semiconductor chip 200 may be electrically connected to the optical converter 113 through the third upper wiring patterns 155c.

The first dummy chip 300 may be formed on the upper wiring layer 150. Additionally, the first dummy chip 300 may be disposed to overlap with the first area A1 in the first direction (or the Z-axis direction). As the second semiconductor chip 200 and the first dummy chip 300 are disposed together on the upper wiring layer 150, heat can be evenly or substantially evenly distributed within the semiconductor package 10, and the structural balance of the semiconductor package 10 can be maintained, or substantially so. As a result, warpage can be reduced, and a semiconductor package 10 with improved performance and reliability can be provided.

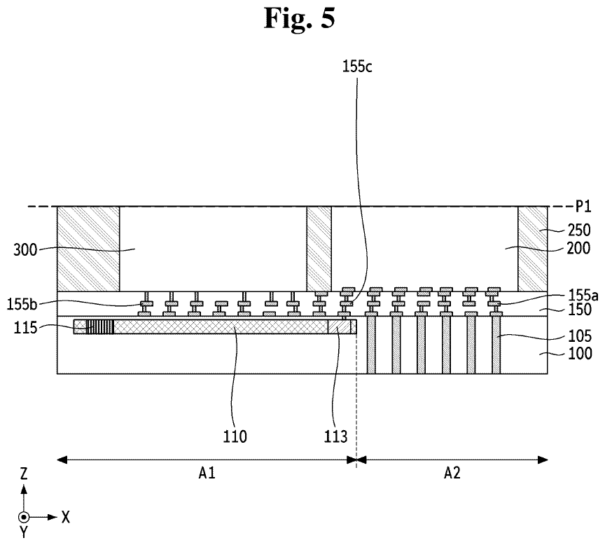

Referring to FIG. 5, the semiconductor package 10 may include the encapsulation layer 250 that seals the first dummy chip 300 and the second semiconductor chip 200. The encapsulation layer 250 may be formed of (for example, include) a material that is optically transparent. For example, the encapsulation layer 250 may include borosilicate glass, silica glass, MMA, and/or PC, etc., but example embodiments are not limited thereto. Accordingly, optical signals input through the optical fiber 500 can be transmitted to the coupler 115.

The upper surfaces of the first dummy chip 300 and the second semiconductor chip 200 may be positioned on the same plane. For example, the upper surfaces of the first dummy chip 300 and the second semiconductor chip 200 may both be located on the first plane P1.

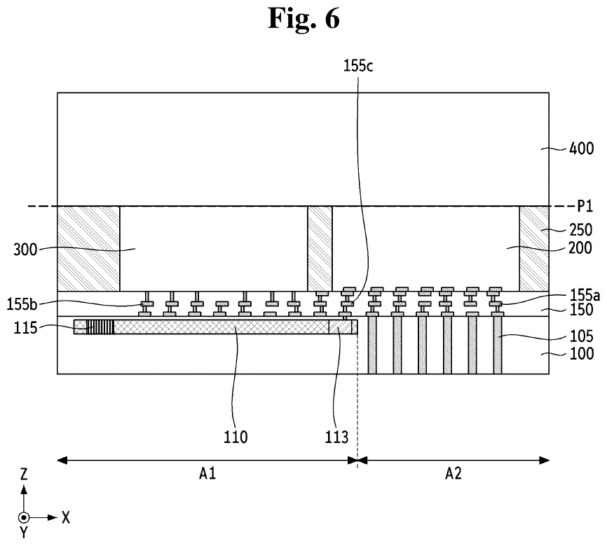

Referring to FIG. 6, the second dummy chip 400 may be formed on the first dummy chip 300 and the second semiconductor chip 200. The second dummy chip 400 may be formed to match the height of the semiconductor package 10 with that of an adjacent semiconductor package. This will be described later in further detail.

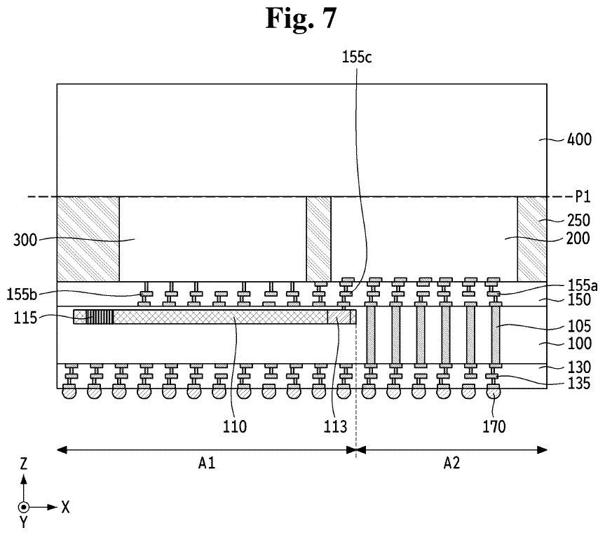

Referring to FIG. 7, the lower wiring layer 130 may be formed on the lower portion of the first semiconductor chip 100. The lower wiring layer 130 may include a plurality of lower wiring patterns 135. At least one of the lower wires 135 may be electrically connected to the vertical wires 105, installed on the first semiconductor chip 100.

A plurality of external connection terminals 170 may be attached to the lower portion of the lower wiring layer 130. The external connection terminals 170 can connect the semiconductor package 10 to the outside. In some example embodiments, the external connection terminals 170 may be or include solder bumps and/or solder balls. The connection terminals 170 may be formed of, for example, Cu, Al, Ag, Sn, Au, alloys thereof, and/or solder, but example embodiments are not limited thereto.

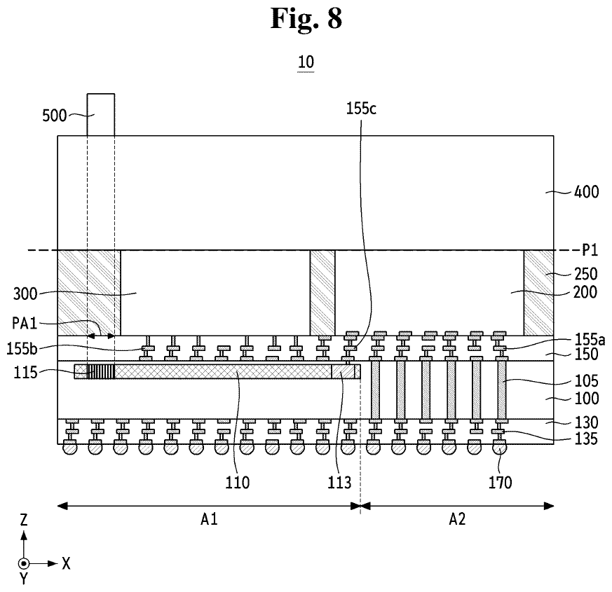

Referring to FIG. 8, the optical fiber 500 may be formed on the second dummy chip 400. Additionally, the optical fiber 500 may be formed to overlap with the coupler 115 in the first direction (or the Z-axis direction). Accordingly, optical signals input through the optical fiber 500 can be transmitted to the coupler 115. However, example embodiments are not limited thereto. For example, the optical fiber 500 may also be formed in an inclined shape.

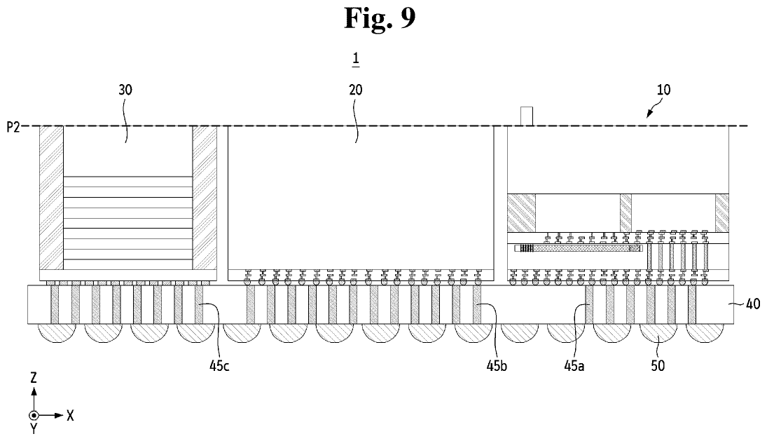

FIG. 9 is a diagram illustrating a semiconductor package that includes the semiconductor package of FIG. 1.

Referring to FIG. 9, a semiconductor package 1 may include a first semiconductor package 10, a second semiconductor package 20, and a third semiconductor package 30. The first, second, and third semiconductor packages 10, 20, and 30 may be mounted on a first substrate 40. In some example embodiments, the first substrate 40 may be or include an interposer substrate.

The first semiconductor package 10 may be the same as the semiconductor package described above with reference to FIGS. 1 through 8.

In some example embodiments, the second semiconductor package 20 may include a processor chip. For example, the second semiconductor package 20 may include a central processing unit (CPU), a graphics processing unit (GPU), a microprocessor, a microcontroller, an application processor (AP), a digital signal processing core, and/or an application-specific integrated circuit (ASIC) chip that includes an interface for signal exchange, but example embodiments are not limited thereto.

In some example embodiments, the third semiconductor package 30 may include, for example, a high-bandwidth memory (HBM) device. An HBM package may include, example, a wideband interface for faster data exchange with the processor chip. The HBM package may include, for example, a through-silicon via (TSV) input/output (I/O) structure with a large number of TSV structures, enabling the implementation of the wideband interface, but example embodiments are not limited thereto.

Referring to FIGS. 1 and 9, a second dummy chip 400 installed in the first semiconductor package 10 may be formed on a first dummy chip 300 and a second semiconductor chip 200. The second dummy chip 400 may be formed to match the height of the first, second, and third semiconductor packages 10, 20, and 30 disposed on the first substrate 40. For example, the first semiconductor package 10 may include the second dummy chip 400 to match the height of the first semiconductor package 10 with that of the neighboring second and third semiconductor packages 20 and 30. This ensures that the upper surfaces of the first, second, and third semiconductor packages 10, 20, and 30 are positioned on the same plane. For example, the upper surfaces of the first, second, and third semiconductor packages 10, 20, and 30 may all be positioned on a second plane P2.

The first substrate 40 may be or include a silicon interposer or a redistribution interposer with a plurality of wirings formed inside. The first, second, and third semiconductor packages 10, 20, and 30 may be electrically connected to one another or to the outside through first interposer wires 45a, second interposer wires 45b, and third interposer wires 45c inside the first substrate 40.

A plurality of external connection members 50 may be disposed on the lower portion of the first substrate 40 for electrical connection to external devices. For example, the external connection members 50 may be or include solder balls, but example embodiments are not limited thereto.

In some example embodiments, the first and second semiconductor packages 10 and may be mounted on the first substrate 40 by flip-chip bonding using a plurality of micro bumps.

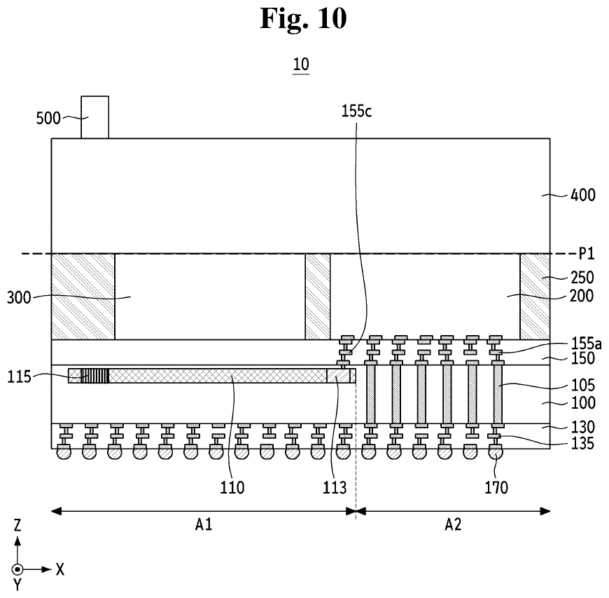

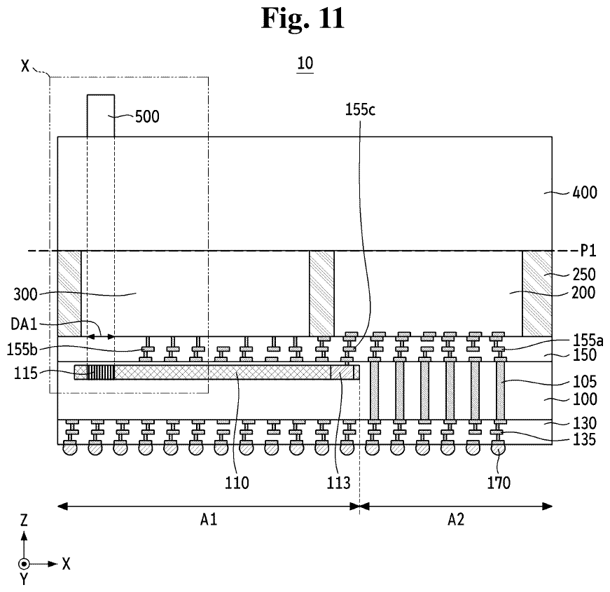

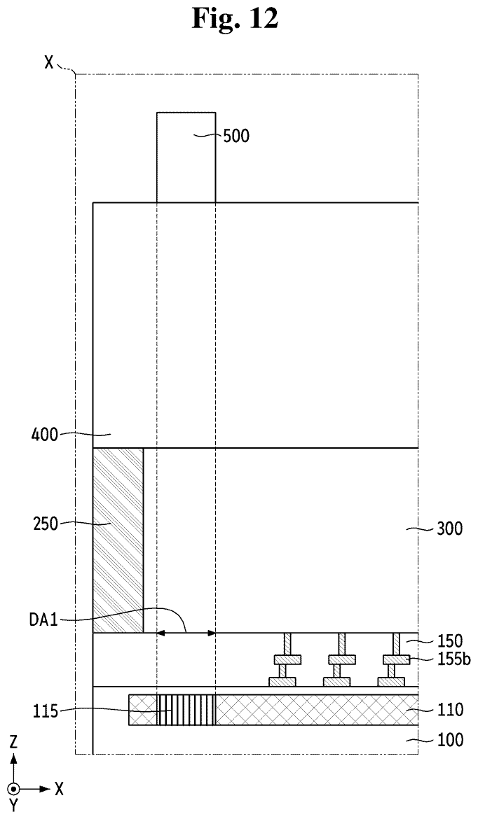

FIGS. 10 and 11 are diagrams illustrating semiconductor packages according to some example embodiments. FIG. 12 is an enlarged view explaining region X of FIG. 11. The semiconductor packages of FIGS. 10 and 11 are similar to the semiconductor package of FIG. 1, and thus will hereinafter be described, focusing mainly on the differences from what has been described above with reference to FIG. 1.

Referring to FIG. 10, a semiconductor package 10 may include a first semiconductor chip 100, an upper wiring layer 150, a lower wiring layer 130, a second semiconductor chip 200, a first dummy chip 300, a second dummy chip 400, and an optical fiber 500.

The first semiconductor chip 100 may include a first area A1 and a second area A2 on a substrate. An optical conversion device may be installed in the first area A1. Vertical wires 105 may be installed in the second area A2. For example, the first semiconductor chip 100 may be or include a PIC.

In some example embodiments, the optical conversion device may include a coupler 115, a waveguide 110, and an optical converter 113.

The vertical wires 105 may be connected to first upper wiring patterns 155a of the upper wiring layer 150 and may be electrically connected to lower wiring patterns 135 of the lower wiring layer 130. Accordingly, the configuration within the semiconductor package 10 can be electrically connected to the outside.

The upper wiring layer 150 may be formed on the first semiconductor chip 100. In some example embodiments, the upper wiring layer 150 may include the first upper wiring patterns 155a and second upper wiring patterns 155b. In other words, the upper wiring layer 150 may not include dummy wiring patterns below the first dummy chip 300.

The first upper wiring patterns 155a may be installed to overlap with the second semiconductor chip 200 in a first direction (or a Z-axis direction), and may be connected to the vertical wires 105 and the second semiconductor chip 200. The second upper wiring patterns 155b may be connected to the optical converter 113 and the second semiconductor chip 200. Accordingly, electrical signals generated by the optical converter 113 can be transmitted to the second semiconductor chip 200, and electrical signals can be transmitted from the second semiconductor chip 200 to the optical converter 113.

The second semiconductor chip 200 may be formed on the upper wiring layer 150. Additionally, the second semiconductor chip 200 may be disposed to overlap (for example, at least partially overlap) with the second area A2 in the first direction (or the Z-axis direction).

The first dummy chip 300 may be formed on the upper wiring layer 150. Additionally, the first dummy chip 300 may be disposed to overlap with the first area A1 in the first direction (or the Z-axis direction). As the second semiconductor chip 200 and the first dummy chip 300 are disposed together on the upper wiring layer 150, heat can be evenly distributed within the semiconductor package 10, and the structural balance of the semiconductor package 10 can be maintained. Accordingly, warpage can be reduced, and a semiconductor package 10 with improved performance and reliability can be provided.

The upper surfaces of the first dummy chip 300 and the second semiconductor chip 200 may be positioned on the same plane. For example, the upper surfaces of the first dummy chip 300 and the second semiconductor chip 200 may both be located on a first plane P1.

The semiconductor package 10 may include an encapsulation layer 250 that seals the first dummy chip 300 and the second semiconductor chip 200. The encapsulation layer 250 may be formed of (for example, include) a material that is optically transparent.

The second dummy chip 400 may be formed on the first dummy chip 300 and the second semiconductor chip 200. The second dummy chip 400 may include a material such as silicon, silicon oxide, or a metal. The second dummy chip 400 may be formed to match the height of the semiconductor package 10 with that of an adjacent semiconductor package 10.

The optical fiber 500 may be formed on the second dummy chip 400. Additionally, in some example embodiments, the optical fiber 500 may be formed to overlap with the coupler 115 in the first direction (or the Z-axis direction). Accordingly, optical signals input through the optical fiber 500 can be transmitted to the coupler 115. However, inventive concepts are not limited thereto. For example, the optical fiber 500 may also be formed in an inclined shape.

A plurality of external connection terminals 170 may be attached to the lower portion of the lower wiring layer 130. The external connection terminals 170 may connect the semiconductor package 10 to the outside.

Referring to FIGS. 11 and 12, a semiconductor package 10 may include a first semiconductor chip 100, an upper wiring layer 150, a lower wiring layer 130, a second semiconductor chip 200, a first dummy chip 300, a second dummy chip 400, and an optical fiber 500.

The first semiconductor chip 100 may include a first area A1 and a second area A2 on a substrate. An optical conversion device may be installed in the first area A1. Vertical wires 105 may be installed in the second area A2. For example, the first semiconductor chip 100 may be or include a PIC.

In some example embodiments, the optical conversion device may include a coupler 115, a waveguide 110, and an optical converter 113.

The vertical wires 105 may be connected to first upper wiring patterns 155a of the upper wiring layer 150 and may be electrically connected to lower wiring patterns 135 of the lower wiring layer 130. Accordingly, the configuration within the semiconductor package 10 can be electrically connected to the outside.

The upper wiring layer 150 may be formed on the first semiconductor chip 100. The upper wiring layer 150 may include the first upper wiring patterns 155a, second upper wiring patterns 155b, and third upper wiring patterns 155c.

The first upper wiring patterns 155a may be installed to overlap with the second semiconductor chip 200 in the first direction (or the Z-axis direction), and may be connected to the vertical wires 105 and the second semiconductor chip 200. The second upper wiring patterns 155b may be installed to overlap with the first dummy chip 300 in the first direction (or the Z-axis direction). The second upper wiring patterns 155b may not be electrically connected to the first dummy chip 300. For example, the second upper wiring patterns 155b may be or include dummy wiring patterns. Additionally, the second upper wiring patterns 155b may not be electrically connected to the first upper wiring patterns 155a. This allows the upper wiring layer 150 to be provided with a uniform metal density, which can reduce or prevent dishing and erosion phenomena that may occur during a CMP process. In other words, a semiconductor package with improved reliability and quality can be provided. The third upper wiring patterns 155c may be connected to the optical converter 113 and the second semiconductor chip 200. Accordingly, electrical signals generated by the optical converter 113 can be transmitted to the second semiconductor chip 200, and electrical signals can be transmitted from the second semiconductor chip 200 to the optical converter 113.

The second semiconductor chip 200 may be formed on the upper wiring layer 150. Additionally, the second semiconductor chip 200 may be disposed to overlap with the second area A2 in the first direction (or the Z-axis direction).

The first dummy chip 300 may be formed on the upper wiring layer 150. Additionally, the first dummy chip 300 may be disposed to overlap with the first area A1 in the first direction (or the Z-axis direction). As the second semiconductor chip 200 and the first dummy chip 300 are disposed together on the upper wiring layer 150, heat can be evenly distributed within the semiconductor package 10, and the structural balance of the semiconductor package 10 can be maintained. As a result, warpage can be reduced, and a semiconductor package 10 with improved performance and reliability can be provided. The first dummy chip 300 may include a material(s) such as, for example, silicon, silicon oxide, and/or a metal, but example embodiments are not limited thereto.

The second dummy chip 400 may be formed on the first dummy chip 300 and the second semiconductor chip 200. The second dummy chip 400 may include the same material as the first dummy chip 300. For example, the second dummy chip 400 may include a material such as silicon, silicon oxide, or a metal, and have identical or similar physical characteristics to the first dummy chip 300. For example, the refractive indexes of the first and second dummy chips 300 and 400 may be the same, or substantially so.

The first dummy chip 300 may include a first dummy area DA1. The first dummy area DA1 may be formed to overlap with the coupler 115 and the second dummy chip 400 in the first direction (or the Z-axis direction). Accordingly, as optical signals transmitted from the optical fiber 500 sequentially pass through the second dummy chip 400 and the first dummy chip 300 with the same refractive index, the interface loss of the optical signals can be reduced or minimized. As a result, a semiconductor package with improved performance can be provided.

The entire area of the coupler 115 is illustrated as overlapping with the first dummy chip 300, but example embodiments are not limited thereto. For example, only part of the area of the coupler 115 may overlap with the first dummy chip 300.

The upper surfaces of the first dummy chip 300 and the second semiconductor chip 200 may be positioned on the same plane. For example, the upper surfaces of the first dummy chip 300 and the second semiconductor chip 200 may both be located on a first plane P1.

The semiconductor package 10 may include an encapsulation layer 250 that seals the first dummy chip 300 and the second semiconductor chip 200.

The optical fiber 500 may be formed on the second dummy chip 400. Additionally, in some example embodiments, the optical fiber 500 may be formed to overlap with the coupler 115 in the first direction (or the Z-axis direction). Accordingly, optical signals input through the optical fiber 500 can be transmitted to the coupler 115. However, inventive concepts are not limited thereto. For example, the optical fiber 500 may also be formed in an inclined shape.

A plurality of external connection terminals 170 may be attached to the lower portion of the lower wiring layer 130. The external connection terminals 170 may connect the semiconductor package 10 to the outside.

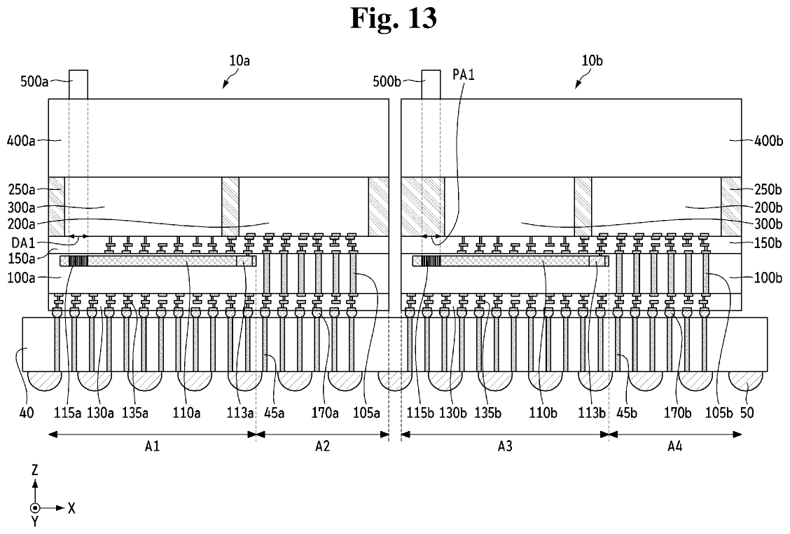

FIG. 13 is a diagram illustrating a semiconductor package according to some example embodiments. A first semiconductor package 10a of FIG. 13 may be the same as the semiconductor package 10 of FIG. 11. A second semiconductor package 10b of FIG. 13 may be the same as the semiconductor package 10 of FIGS. 1 through 8. For the convenience of explanation, content that overlaps with what has been described above with reference to FIGS. 1 through 8 and FIG. 11 will be omitted.

Referring to FIG. 13, the first and second semiconductor packages 10a and 10b may be disposed on a first substrate 40.

In some example embodiments, the first substrate 40 may be an interposer substrate.

The first semiconductor package 10a may include a first semiconductor chip 100a, a first upper wiring layer 150a, a first lower wiring layer 130a, a second semiconductor chip 200a, a first dummy chip 300a, a second dummy chip 400a, and a first optical fiber 500a.

The first semiconductor chip 100a may include a first area A1 and a second area A2 on a substrate. A first optical conversion device may be installed in the first area A1. First vertical wires 105a may be installed in the second area A2. For example, the first semiconductor chip 100a may be a PIC, but example embodiments are not limited thereto.

The first upper wiring layer 150a may be formed on the first semiconductor chip 100a.

The second semiconductor chip 200a may be formed on the first upper wiring layer 150a. Additionally, the second semiconductor chip 200a may be disposed to overlap (for example, at least partially overlap) with the second area A2 in a first direction (or a Z-axis direction).

The first dummy chip 300a may be formed on the first upper wiring layer 150a. Additionally, the first dummy chip 300a may be disposed to overlap (for example, at least partially overlap) with the first area A1 in the first direction (or the Z-axis direction). As the second semiconductor chip 200a and the first dummy chip 300a are disposed together on the first upper wiring layer 150a, heat can be evenly distributed within the first semiconductor package 10a, and the structural balance of the first semiconductor package 10a can be maintained. As a result, warpage can be reduced, and a first semiconductor package 10a with improved performance and reliability can be provided. The first dummy chip 300a may include, for example, a material such as silicon, silicon oxide, or a metal, but example embodiments are not limited thereto.

The second dummy chip 400a may be formed on the first dummy chip 300a and the second semiconductor chip 200a. The second dummy chip 400a may include the same material as the first dummy chip 300a. For example, the second dummy chip 400a may include a material such as silicon, silicon oxide, or a metal, and have identical or similar physical characteristics to the first dummy chip 300a, but example embodiments are not limited thereto. For example, the refractive indexes of the first and second dummy chips 300a and 400a may be the same, or substantially so.

The first dummy chip 300a may include a first dummy area DA1. The first dummy area DA1 may be formed to overlap (for example, at least partially overlap) with the first coupler 115a and the second dummy chip 400a in the first direction (or the Z-axis direction). Accordingly, as optical signals transmitted from the first optical fiber 500a sequentially pass through the second dummy chip 400a and the first dummy chip 300a with the same refractive index, the interface loss of the optical signals can be reduced or minimized. As a result, a semiconductor package with improved performance can be provided.

The entire area of the first coupler 115a is illustrated as overlapping with the first dummy chip 300a, but example embodiments are not limited thereto. For example, only part of the area of the first coupler 115a may overlap with the first dummy chip 300a.

The first semiconductor package 10a may include a first encapsulation layer 250a that seals the first dummy chip 300a and the second semiconductor chip 200a.

The first optical fiber 500a may be formed on the second dummy chip 400a. Additionally, in some example embodiments, the first optical fiber 500a may be formed to overlap (for example, at least partially overlap) with the first coupler 115a in the first direction (or the Z-axis direction). Accordingly, optical signals input through the first optical fiber 500a can be transmitted to the first coupler 115a. However, inventive concepts are not limited thereto. Alternatively, the first optical fiber 500a may be formed in an inclined shape.

A plurality of first external connection terminals 170a may be attached to the lower portion of the first lower wiring layer 130a. The first external connection terminals 170a may connect the first semiconductor package 10a and the first substrate 40.

The second semiconductor package 10b may include a third semiconductor chip 100b, a second upper wiring layer 150b, a second lower wiring layer 130b, a fourth semiconductor chip 200b, a third dummy chip 300b, a fourth dummy chip 400b, and a second optical fiber 500b.

The third semiconductor chip 100b may include a third area A3 and a fourth area A4 on a substrate. A second optical conversion device may be installed in the third area A3. Second vertical wires 105b may be installed in the fourth area A4. For example, the third semiconductor chip 100b may be or include a PIC.

The second upper wiring layer 150b may be formed on the third semiconductor chip 100b.

The third semiconductor chip 100b may be formed on the second upper wiring layer 150b. Additionally, the fourth semiconductor chip 200b may be disposed to overlap (for example, at least partially overlap) with the fourth area A4 in the first direction (or the Z-axis direction).

The third dummy chip 300b may be formed on the second upper wiring layer 150b. Additionally, the third dummy chip 300b may be disposed to overlap (for example, at least partially overlap) with the third area A3 in the first direction (or the Z-axis direction). As the fourth semiconductor chip 200b and the third dummy chip 300b are disposed together on the second upper wiring layer 150b, heat can be evenly distributed within the second semiconductor package 10b, and the structural balance of the second semiconductor package 10b can be maintained. As a result, warpage can be reduced, and a second semiconductor package 10b with improved performance and reliability can be provided.

The second semiconductor package 10b may include a second encapsulation layer 250b that seals the third dummy chip 300b and the fourth semiconductor chip 200b.

The second encapsulation layer 250b may include a first encapsulation area PA1. The first encapsulation area PA1 may be formed to overlap (for example, at least partially overlap) with the second coupler 115b and the fourth dummy chip 400b in the first direction (or the Z-axis direction). Accordingly, optical signals transmitted from the second optical fiber 500b can be transmitted to the second coupler 115b, sequentially passing through the fourth dummy chip 400b and the second encapsulation layer 300b with different refractive indexes.

In other words, the first semiconductor package 10a may reduce or minimize the interface loss of the optical signals compared to the second semiconductor package 10b. As a result, a semiconductor package with improved performance can be provided.

The fourth dummy chip 400b may be formed on the third dummy chip 300b and the fourth semiconductor chip 200b. The fourth dummy chip 400b may be formed to match the height of the second semiconductor package 10b with that of an adjacent semiconductor package (for example, the first semiconductor package 10a).

The second optical fiber 500b may be formed on the fourth dummy chip 400b. Additionally, in some example embodiments, the second optical fiber 500b may be formed to overlap (for example, at least partially overlap) with the second coupler 115b in the first direction (or the Z-axis direction). Accordingly, optical signals input through the second optical fiber 500b can be transmitted to the second coupler 115b. However, inventive concepts are not limited thereto. Alternatively, the second optical fiber 500b may be formed in an inclined shape.

A plurality of second external connection terminals 170b may be attached to the lower portion of the second lower wiring layer 130b. The second external connection terminals 170b may connect the second semiconductor package 10b to the first substrate 40.

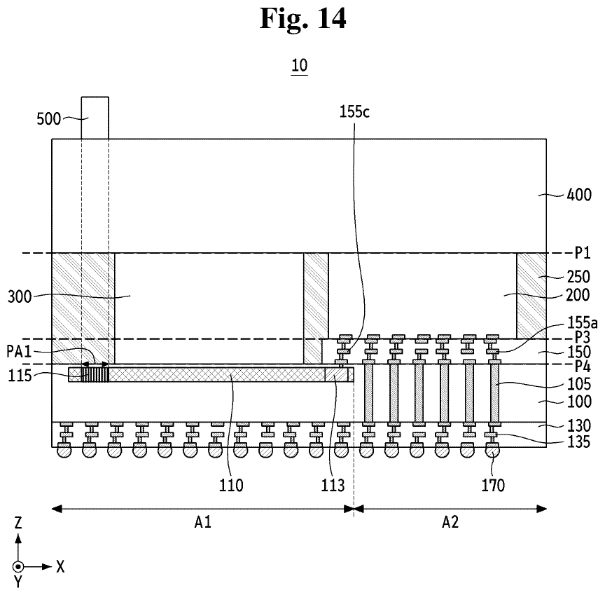

FIGS. 14 through 16 are diagrams illustrating semiconductor packages according to some example embodiments. The semiconductor packages of FIGS. 14 through 16 are similar to the semiconductor package of FIG. 1, and thus will hereinafter be described, focusing mainly on the differences from what has been described above with reference to FIG. 1.

Referring to FIG. 14, a semiconductor package 10 may include a first semiconductor chip 100, an upper wiring layer 150, a lower wiring layer 130, a second semiconductor chip 200, a first dummy chip 300, a second dummy chip 400, and an optical fiber 500.

The first semiconductor chip 100 may include a first area A1 and a second area A2 on a substrate. An optical conversion device may be installed in the first area A1. Vertical wires 105 may be installed in the second area A2. For example, the first semiconductor chip 100 may be or include a PIC.

In some example embodiments, the optical conversion device may include a coupler 115, a waveguide 110, and an optical converter 113.

The vertical wires 105 may be connected to first upper wiring patterns 155a of the upper wiring layer 150 and may be electrically connected to lower wiring patterns 135 of the lower wiring layer 130. Accordingly, the configuration within the semiconductor package 10 can be electrically connected to the outside.

The upper wiring layer 150 may be formed on the first semiconductor chip 100 to overlap (for example, at least partially overlap) with the second area A2. In some example embodiments, the upper wiring layer 150 may include the first upper wiring patterns 155a and second upper wiring patterns 155c.

The first upper wiring patterns 155a may be installed to overlap (for example, at least partially overlap) with the second semiconductor chip 200 in a first direction (or a Z-axis direction) and may be connected to the vertical wires 105 and the second semiconductor chip 200. The second upper wiring patterns 155c may be connected to the optical converter 113 and the second semiconductor chip 200. Accordingly, electrical signals generated by the optical converter 113 can be transmitted to the second semiconductor chip 200, and electrical signals can be transmitted from the second semiconductor chip 200 can be transmitted to the optical converter 113.

The second semiconductor chip 200 may be formed on the upper wiring layer 150. Additionally, the second semiconductor chip 200 may be disposed to overlap (for example, at least partially overlap) with the second area A2 in the first direction (or the Z-axis direction).

The first dummy chip 300 may be formed on the first semiconductor chip 100. As the second semiconductor chip 200 and the first dummy chip 300 are disposed together on the upper wiring layer 150, heat can be evenly distributed within the semiconductor package 10, and the structural balance of the semiconductor package 10 can be maintained. As a result, warpage can be reduced, and a semiconductor package 10 with improved performance and reliability can be provided.

Additionally, the first dummy chip 300 may be formed to directly contact the first semiconductor chip 100 without the upper wiring layer 150 interposed therebetween. In other words, the bottom surface of the first dummy chip 300 may be positioned lower than the bottom surface of the second semiconductor chip 200. For example, the bottom surface of the second semiconductor chip 200 may be located on a third plane P3, and the bottom surface of the first dummy chip 300 may be located on a fourth plane P4. In the first direction (or the Z-axis direction), the third plane P3 may be positioned lower than the fourth plane P4. This configuration reduces or minimizes the interfaces with different refractive indexes that optical signals pass through before reaching the coupler 115, thereby reducing or minimizing the interface loss of the optical signals. As a result, a semiconductor package with improved performance can be provided.

On the other hand, the upper surfaces of the first dummy chip 300 and the second semiconductor chip 200 may be positioned on the same plane. For example, the upper surfaces of the first dummy chip 300 and the second semiconductor chip 200 may both be located on a first plane P1.

The semiconductor package 10 may include an encapsulation layer 250 that seals the first dummy chip 300 and the second semiconductor chip 200.

The second dummy chip 400 may be formed on the first dummy chip 300 and the second semiconductor chip 200. The second dummy chip 400 may include the same material as the first dummy chip 300. For example, the second dummy chip 400 may include a material such as silicon, silicon oxide, or a metal, and have identical or similar physical properties to the first dummy chip 300, but example embodiments are not limited thereto. For example, the refractive indexes of the first and second dummy chips 300 and 400 may be the same, or substantially so. The second dummy chip 400 may be formed to match the height of the semiconductor package 10 with that of an adjacent semiconductor package 10.

The optical fiber 500 may be formed on the second dummy chip 400. Additionally, in some example embodiments, the optical fiber 500 may be formed to overlap (for example, at least partially overlap) with the coupler 115 in the first direction (or the Z-axis direction). Accordingly, optical signals input through the optical fiber 500 can be transmitted to the coupler 115. However, inventive concepts are not limited thereto. For example, the optical fiber 500 may also be formed in an inclined shape.

A plurality of external connection terminals 170 may be attached to the lower portion of the lower wiring layer 130. The external connection terminals 170 may connect the semiconductor package 10 to the outside. In some example embodiments, the external connection terminals 170 may be solder bumps or solder balls.

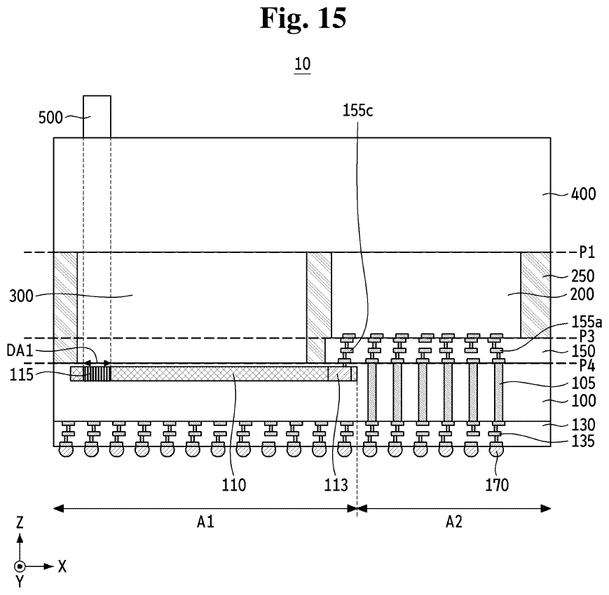

Referring to FIG. 15, a semiconductor package 10 may include a first semiconductor chip 100, an upper wiring layer 150, a lower wiring layer 130, a second semiconductor chip 200, a first dummy chip 300, a second dummy chip 400, and an optical fiber 500.

The first semiconductor chip 100 may include a first area A1 and a second area A2 on a substrate. An optical conversion device may be installed in the first area A1. Vertical wires 105 may be installed in the second area A2. For example, the first semiconductor chip 100 may be or include a PIC.

In some example embodiments, the optical conversion device may include a coupler 115, a waveguide 110, and an optical converter 113.

The vertical wires 105 may be connected to first upper wiring patterns 155a of the upper wiring layer 150 and may be electrically connected to lower wiring patterns 135 of the lower wiring layer 130. Accordingly, the configuration within the semiconductor package 10 can be electrically connected to the outside.

The upper wiring layer 150 may be formed on the first semiconductor chip 100 to overlap (for example, at least partially overlap) with the second area A2. In some example embodiments, the upper wiring layer 150 may include the first upper wiring patterns 155a and second upper wiring patterns 155c.

The first upper wiring patterns 155a may be installed to overlap (for example, at least partially overlap) with the second semiconductor chip 200 in a first direction (or a Z-axis direction) and may be connected to the vertical wires 105 and the second semiconductor chip 200. The second upper wiring patterns 155c may be connected to the optical converter 113 and the second semiconductor chip 200. Accordingly, electrical signals generated by the optical converter 113 can be transmitted to the second semiconductor chip 200, and electrical signals from the second semiconductor chip 200 can be transmitted to the optical converter 113.

The second semiconductor chip 200 may be formed on the upper wiring layer 150. Additionally, the second semiconductor chip 200 may be disposed to overlap (for example, at least partially overlap) with the second area A2 in the first direction (or the Z-axis direction).

The first dummy chip 300 may be formed on the first semiconductor chip 100. As the second semiconductor chip 200 and the first dummy chip 300 are disposed together on the upper wiring layer 150, heat can be evenly distributed within the semiconductor package 10, and the structural balance of the semiconductor package 10 can be maintained. As a result, warpage can be reduced, and a semiconductor package 10 with improved performance and reliability can be provided.

The second dummy chip 400 may be formed on the first dummy chip 300 and the second semiconductor chip 200. The second dummy chip 400 may include the same material as the first dummy chip 300. For example, the second dummy chip 400 may include a material such as silicon, silicon oxide, or a metal, and may have identical or similar physical properties to the first dummy chip 300. For example, the refractive indexes of the first dummy chip 300 and the second dummy chip 400 may be the same, or substantially so. The second dummy chip 400 may be formed to match the height of the semiconductor package 10 with that of an adjacent semiconductor package 10.

The first dummy chip 300 may include a first dummy area DA1. The first dummy area DA1 may be formed to overlap (for example, at least partially overlap) with the coupler 115 and the second dummy chip 400 in the first direction (or the Z-axis direction). Accordingly, as optical signals transmitted from the optical fiber 500 sequentially pass through the second dummy chip 400 and the first dummy chip 300 with the same refractive index, the interface loss of the optical signals can be reduced or minimized. As a result, a semiconductor package with improved performance can be provided.

The entire area of the coupler 115 is illustrated as overlapping with the first dummy chip 300, but example embodiments are not limited thereto. For example, only part of the area of the coupler 115 may overlap with the first dummy chip 300.

Additionally, the first dummy chip 300 may be formed to directly contact the first semiconductor chip 100 without the upper wiring layer 150 interposed therebetween. In other words, the bottom surface of the first dummy chip 300 may be positioned lower than the bottom surface of the second semiconductor chip 200. For example, the bottom surface of the second semiconductor chip 200 may be located on a third plane P3, and the bottom surface of the first dummy chip 300 may be located on a fourth plane P4. In the first direction (or the Z-axis direction), the third plane P3 may be positioned lower than the fourth plane P4. This configuration may reduce or minimize the interfaces with different refractive indexes that optical signals pass through before reaching the coupler 115, thereby reducing or minimizing the interface loss of the optical signals. Accordingly, a semiconductor package with improved performance can be provided.

On the other hand, the upper surfaces of the first dummy chip 300 and the second semiconductor chip 200 may be positioned on the same plane. For example, the upper surfaces of the first dummy chip 300 and the second semiconductor chip 200 may both be located on a first plane P1.

The semiconductor package 10 may include an encapsulation layer 250 that seals the first dummy chip 300 and the second semiconductor chip 200.

The optical fiber 500 may be formed on the second dummy chip 400. Additionally, in some example embodiments, the optical fiber 500 may be formed to overlap (for example, at least partially overlap) with the coupler 115 in the first direction (or the Z-axis direction). Accordingly, optical signals input through the optical fiber 500 can be transmitted to the coupler 115. However, inventive concepts are not limited thereto. For example, the optical fiber 500 may also be formed in an inclined shape.

A plurality of external connection terminals 170 may be attached to the lower portion of the lower wiring layer 130. The external connection terminals 170 may connect the semiconductor package 10 to the outside.

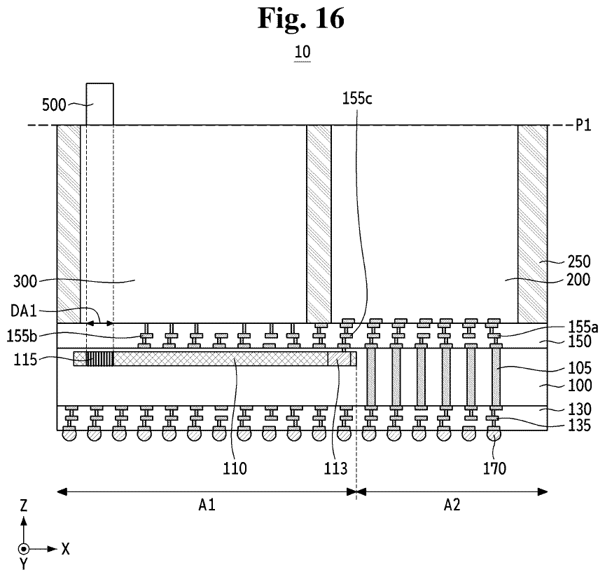

Referring to FIG. 16, a semiconductor package 10 may include a first semiconductor chip 100, an upper wiring layer 150, a lower wiring layer 130, a second semiconductor chip 200, a first dummy chip 300, a second dummy chip 400, and an optical fiber 500.

The first semiconductor chip 100 may include a first area A1 and a second area A2 on a substrate. An optical conversion device may be installed in the first area A1. Vertical wires 105 may be installed in the second area A2. For example, the first semiconductor chip 100 may, for example, be or include a PIC.

In some example embodiments, the optical conversion device may include a coupler 115, a waveguide 110, and an optical converter 113.

The vertical wires 105 may be connected to first upper wiring patterns 155a of the upper wiring layer 150 and may be electrically connected to lower wiring patterns 135 of the lower wiring layer 130. Accordingly, the configuration within the semiconductor package 10 can be electrically connected to the outside.

The upper wiring layer 150 may be formed on the first semiconductor chip 100. The upper wiring layer 150 may include the first upper wiring patterns 155a, second upper wiring patterns 155b, and third upper wiring patterns 155c.

The first upper wiring patterns 155a may be installed to overlap (for example, at least partially overlap) with the second semiconductor chip 200 in a first direction (or a Z-axis direction) and may be connected to the vertical wires 105 and the second semiconductor chip 200. The second upper wiring patterns 155b may be installed to overlap (for example, at least partially overlap) with the first dummy chip 300 in the first direction (or the Z-axis direction). The second upper wiring patterns 155b may not be electrically connected to the first dummy chip 300. Additionally, the second upper wiring patterns 155b may not be electrically connected to the first upper wiring patterns 155a. For example, the second upper wiring patterns 155b may be or include dummy wiring patterns. This allows the upper wiring layer 150 to be provided with a uniform metal density, which can reduce or prevent dishing and erosion phenomena that may occur during a CMP process. In other words, a semiconductor package with improved reliability and quality can be provided. The third upper wiring patterns 155c may be connected to the optical converter 113 and the second semiconductor chip 200. Accordingly, electrical signals generated by the optical converter 113 can be transmitted to the second semiconductor chip 200, and electrical signals from the second semiconductor chip 200 can be transmitted to the optical converter 113.

The second semiconductor chip 200 may be formed on the upper wiring layer 150. Additionally, the second semiconductor chip 200 may be disposed to overlap (for example, at least partially overlap) with the second area A2 in the first direction (or the Z-axis direction).

The first dummy chip 300 may be formed on the upper wiring layer 150. Additionally, the first dummy chip 300 may be disposed to overlap (for example, at least partially overlap) with the first area A1 in the first direction (or the Z-axis direction). As the second semiconductor chip 200 and the first dummy chip 300 are disposed together on the upper wiring layer 150, heat can be evenly distributed within the semiconductor package 10, and the structural balance of the semiconductor package 10 can be maintained. Accordingly, warpage can be reduced, and a semiconductor package 10 with improved performance and reliability can be provided.

The upper surfaces of the first dummy chip 300 and the second semiconductor chip 200 may be positioned on the same plane. For example, the upper surfaces of the first dummy chip 300 and the second semiconductor chip 200 may both be located on a first plane P1.

The semiconductor package 10 may include an encapsulation layer 250 that seals the first dummy chip 300 and the second semiconductor chip 200. The encapsulation layer 250 may be, for example, formed of a material that is optically transparent.

The optical fiber 500 may be formed on the first dummy chip 300. Additionally, in some example embodiments, the optical fiber 500 may be formed to overlap (for example, at least partially overlap) with the coupler 115 in the first direction (or the Z-axis direction). Accordingly, optical signals input through the optical fiber 500 can be transmitted to the coupler 115. However, inventive concepts are not limited thereto. For example, the optical fiber 500 may also be formed in an inclined shape.

A plurality of external connection terminals 170 may be attached to the lower portion of the lower wiring layer 130. The external connection terminals 170 may connect the semiconductor package 10 to the outside.

While some example embodiments of inventive concepts have been described with reference to the accompanying drawings, the present disclosure are not limited to these example embodiments, and various modifications can be made in other forms. Those ordinarily skilled in the art to which inventive concepts pertain will understand that the technical spirit or essential features of inventive concepts can be implemented in other specific forms without changing them. Therefore, the described example embodiments should be understood as illustrative in all respects and not limiting.

What is claimed is:

1. A semiconductor package comprising:
a first semiconductor chip including a first area, a second area, an optical conversion device that is in the first area, and vertical wires that are in the second area, the optical conversion device being configured to receive an optical signal and convert it into an electrical signal;
a first dummy chip on the first semiconductor chip and at least partially overlapping with the first area;
a second semiconductor chip on the first semiconductor chip and at least partially overlapping with the second area;
a wiring layer between the first semiconductor chip and the second semiconductor chip and including first wiring patterns that connect the vertical wires and the second semiconductor chip, and second wiring patterns that at least partially overlap with the first dummy chip; and
a second dummy chip on the first dummy chip and on the second semiconductor chip.

2. The semiconductor package of claim 1, wherein the first wiring patterns and the second wiring patterns are not electrically connected.

3. The semiconductor package of claim 1, further comprising:
an optical fiber on the second dummy chip and configured to receive an optical signal from the outside; and
an encapsulation layer between the first dummy chip and the second semiconductor chip,
wherein the optical conversion device includes a coupler that is configured to receive the optical signal from the optical fiber, a waveguide that is connected to the coupler and configured to transmit the optical signal, and an optical converter that is connected to the waveguide and configured to convert the transmitted optical signal into an electrical signal, and
the optical converter is connected to third wiring patterns and is configured to provide the converted electrical signal to the second semiconductor chip.

4. The semiconductor package of claim 3, wherein
the optical fiber and the coupler at least partially overlap with each other,
the first dummy chip does not overlap with the coupler, and
the encapsulation layer includes a first encapsulation area that at least partially overlaps with the coupler.

5. The semiconductor package of claim 3, wherein
the optical fiber and the coupler at least partially overlap with each other, and
the first dummy chip includes a first dummy area that at least partially overlaps with the coupler.

6. The semiconductor package of claim 5, wherein:
the first dummy area at least partially overlaps with the second dummy chip, and
the first dummy chip and the second dummy chips have the same refractive index.

7. The semiconductor package of claim 5, wherein
the first dummy chip includes a second dummy area that does not overlap with the coupler, and
the second wiring pattern at least partially overlaps with the second dummy area.

8. The semiconductor package of claim 5, further comprising:
a third semiconductor chip including a third area, a fourth area, a second optical conversion device that is in the third area, and second vertical wires that are in the fourth area, the second optical device being configured to receive an optical signal and convert it into an electrical signal;
a third dummy chip on the third semiconductor chip and at least partially overlap with the third area;
a fourth semiconductor chip on the fourth semiconductor chip and at least partially overlapping with the fourth area;
a second encapsulation layer between the third dummy chip and the fourth semiconductor chip;
a second wiring layer between the third semiconductor chip and the fourth semiconductor chip and including fourth wiring patterns that connect the second vertical wires and the fourth semiconductor chip;
a fourth dummy chip on the third dummy chip and on the fourth semiconductor chip; and
a second optical fiber configured to receive an optical signal from the outside, on the fourth dummy chip,
wherein
the second optical conversion device includes a second coupler configured to receive the optical signal from the second optical fiber, a second waveguide that is connected to the second coupler and is configured to transmit the optical signal, and a second optical converter that is connected to the second waveguide and configured to convert the transmitted optical signal into an electrical signal,
the second optical fiber and the second coupler at least partially overlap with each other,
the second encapsulation layer includes a first encapsulation area that at least partially overlaps with the second coupler, and
an intensity of the optical signal transmitted to the coupler is greater than an intensity of the optical signal transmitted to the second coupler.

9. The semiconductor package of claim 1, wherein an upper surface of the first dummy chip and an upper surface of the second semiconductor chip are located on the same plane.

10. The semiconductor package of claim 1, further comprising:
a second wiring layer below the first semiconductor chip and including lower wiring patterns that are connected to the vertical wires; and
solder balls below the second wiring layer and in contact with the lower wiring patterns.

11. A semiconductor package, comprising:
a first semiconductor chip including a first area, a second area, an optical conversion device that is in the first area, and vertical wires that are in the second area, the optical conversion device being configured to receive an optical signal and convert it into an electrical signal;
a first dummy chip on the first semiconductor chip and at least partially overlapping with the first area;
a second semiconductor chip disposed to overlap with the second area;
a wiring layer between the first semiconductor chip and the second semiconductor chip and including first wiring patterns that connect the vertical wires and the second semiconductor chip; and
a second dummy chip on the first dummy chip and on the second semiconductor chip,
wherein the first dummy chip is in direct contact with the first semiconductor chip.

12. The semiconductor package of claim 11, wherein
an upper surface of the first dummy chip and an upper surface of the second semiconductor chip are located on the same plane, and
a lower surface of the first dummy chip is located below a lower surface of the second semiconductor chip.

13. The semiconductor package of claim 12, further comprising:
an optical fiber on the second dummy chip and configured to receive an optical signal from the outside; and
an encapsulation layer between the first dummy chip and the second semiconductor chip,
wherein the optical conversion device includes a coupler that is configured to receive the optical signal from the optical fiber, a waveguide that is connected to the coupler and is configured to transmit the optical signal, and an optical converter that is connected to the waveguide and is configured to convert the transmitted optical signal into an electrical signal, and
the optical converter is connected to third wiring patterns and is configured to provide the converted electrical signal to the second semiconductor chip.

14. The semiconductor package of claim 13, wherein
the optical fiber and the coupler at least partially overlap with each other,
the first dummy chip does not overlap with the coupler, and
the encapsulation layer includes a first encapsulation area that at least partially overlaps with the coupler.

15. The semiconductor package of claim 13, wherein
The optical fiber and the coupler at least partially overlap with each other, and
The first dummy chip includes a first dummy area that at least partially overlaps with the coupler.

16. A semiconductor package, comprising:
an interposer; and
a photonic semiconductor package on the interposer,
wherein the photonic semiconductor package includes a first semiconductor chip including a first area, a second area, an optical conversion device that is in the first area, and vertical wires that are in the second area, the optical conversion device being configured to receive an optical signal and converts it into an electrical signal; a first dummy chip on the first semiconductor chip and at least partially overlapping with the first area; a second semiconductor chip on the first semiconductor chip and at least partially overlapping with the second area; an encapsulation layer between the first dummy chip and the second semiconductor chip; a wiring layer between the first semiconductor chip and the second semiconductor chip, the wiring layer including first wiring patterns and second wiring patterns, the first wiring patterns connecting the vertical wires and the second semiconductor chip, the second wiring patterns between the first dummy chip and the first semiconductor chip; and a second dummy chip on the first dummy chip and on the second semiconductor chip.

17. The semiconductor package of claim 16, further comprising:
a first semiconductor package on the interposer,
wherein an upper surface of the second dummy chip and an upper surface of the first semiconductor package are located on the same plane.

18. The semiconductor package of claim 16, wherein
the photonic semiconductor package includes an optical fiber that is on the second dummy chip and is configured to receive an optical signal from the outside,
the optical conversion device includes a coupler that is configured to receive the optical signal from the optical fiber, a waveguide that is connected to the coupler and is configured to transmit the optical signal, and an optical converter that is connected to the waveguide and is configured to convert the transmitted optical signal into an electrical signal,
the optical fiber and the coupler at least partially overlap with each other, and
the first dummy chip includes a first dummy area that at least partially overlaps with the coupler.

19. The semiconductor package of claim 18, wherein
the wiring layer includes third wiring patterns between the first wiring patterns and the second wiring patterns, and
the third wiring patterns connect the optical converter and the second semiconductor chip.

20. The semiconductor package of claim 18, wherein the photonic semiconductor package further includes a second wiring layer that is below the first semiconductor chip and electrically connects the second semiconductor chip and the interposer, and solder balls that are below the second wiring layer and in contact with the interposer.
